(19) United States
(12) Patent Application Publication
(10) Pub. No.: US 2020/0115067 A1
(43) Pub. Date: Apr. 16, 2020

(54) TEST RIG AND METHOD FOR PASSENGER CABIN MANAGEMENT SYSTEM OF MOBILE PLATFORM

(71) Applicant: BOMBARDIER INC., Dorval (CA)

(72) Inventor: Alessandro FARACI, Anjou (CA)

(21) Appl. No.: 16/609,571

(22) PCT Filed: Apr. 30, 2018
(86) PCT No.: PCT/IB2018/052985

§ 371 Date: Oct. 30, 2019

Related U.S. Application Data
(60) Provisional application No. 62/518,973, filed on Jun. 13, 2017.
(60) Provisional application No. 62/500,337, filed on May 2, 2017.

(51) Int. Cl. B64F 5/10; B64F 5/60; G01R 31/00

(52) U.S. Cl. CPC B64F 5/10; G01R 31/008; B64F 5/60

(57) ABSTRACT

Test rigs and methods for performing functional tests on a cabin management system (CMS) of a passenger cabin of an aircraft or other mobile platform are disclosed. In some embodiments, a test rig comprises a plurality of components of the CMS functionally integrated in a manner representative of the installation of the components in the passenger cabin; and a framework supporting the functionally integrated components. The layout of the components on the framework is non-dimensionally representative of the installation of the components in the passenger cabin.

### CROSS-REFERENCE TO RELATED APPLICATION(S)

This International PCT Patent Application relies for priority on U.S. Provisional Patent Application Ser. No. 62/500,337 filed on May 2, 2017 and 62/518,973 filed on Jun. 13, 2017, the entire content of which is incorporated herein by reference.

### TECHNICAL FIELD

The disclosure relates generally to aircraft and other mobile platforms, and more particularly to testing of systems of mobile platforms.

### BACKGROUND OF THE ART

Performing tests on a cabin management system (CMS) of an aircraft is typically done while the components of the CMS are installed in an actual aircraft that is used for flight testing (i.e., a flight test vehicle). Using a flight test vehicle for such testing can result in inefficiencies in the overall testing and certification schedule of a new aircraft program. For example, delays associated with testing of the CMS can potentially affect the schedule of the flight test vehicle and consequently cause delays in the certification schedule of the new aircraft program.

Another approach for conducting tests on a CMS involves the use of a dimensionally-representative (i.e., 1:1 scale) mock-up of the aircraft passenger cabin into which the components of the CMS are installed. Such mock-ups typically reproduce the passenger cabin as faithfully as possible at least geometrically. For example, the various components of the CMS are installed in the mock-up in their exact respective positions that they would occupy in a corresponding real passenger cabin.

### SUMMARY

In one aspect, the disclosure describes a test rig for performing functional tests on a cabin management system (CMS) of a passenger cabin of an aircraft or other mobile platform. The test rig comprises:

a plurality of components of the CMS functionally integrated in a manner representative of the installation of the components in the passenger cabin; and

a framework supporting the functionally integrated components, the layout of the components on the framework being non-dimensionally representative of the installation of the components in the passenger cabin.

The framework may comprise a generally planar support member to which one or more of the components are attached. The framework may be located at a ground-based facility and the planar support member may be generally vertical relative to a floor of the ground-based facility. The planar support member may be non-parallel to a floor of the ground-based facility.

The support member may comprise a plurality of attachment features configured to permit removable attachment of the components to the support member. The attachment features may comprise holes.

The support member may extend between two posts.

The support member may comprise a grillage.

Components may be attached to opposite generally planar sides of the support member.

The framework may comprise a grillage to which one or more of the components are attached.

One or more of the components may be attached to the framework with a VELCRO strap.

One or more of the components may be attached to the framework with a cable tie.

One or more of the components may be attached to the framework via a rack.

One or more of the components may be electrically grounded to the framework.

The components may be functionally integrated via dimensionally-representative wire harnesses.

The test rig may comprise a power source electrically connected to one or more of the components, the power source being configured to simulate one or more electric busses of the mobile platform.

The framework may comprise a plurality of test rig zones respectively corresponding to passenger cabin zones, the test rig zones respectively supporting one or more of the components associated with the respective passenger cabin zones.

The test rig may comprise two frameworks disposed adjacent one another to define a corridor between the two frameworks.

Each framework may respectively support one or more of the components associated a respective lateral side of the passenger cabin.

One or more of the components supported by one of the frameworks may be functionally connected to one or more of the components supported by the other framework via a wire harness extending across the corridor defined between the two frameworks.

The plurality of components may include one or more line-replaceable units associated with two or more of the following systems of the passenger cabin: a lighting system, a climate control system, a sound system, an information system, an in-flight entertainment system and an internet connectivity system.

Embodiments may include combinations of the above features.

In another aspect, the disclosure describes a method of performing functional tests on a cabin management system (CMS) of a passenger cabin of an aircraft or other mobile platform. The method comprises:

attaching a plurality of components of the CMS to a framework where the layout of the components is non-dimensionally representative of the installation of the components in the passenger cabin;

functionally integrating the components in a manner representative of the installation of the components in the passenger cabin; and

performing one or more functional tests on one or more of the components.

The method may comprise attaching one or more of the components to opposite generally planar sides of the framework.

The method may comprise electrically grounding one or more of the components to the framework.

The method may comprise functionally integrating the components via one or more wire harnesses dimensionally-representative of the installation of the components in the passenger cabin.

The method may comprise attaching the components of the CMS associated with different passenger cabin zones to corresponding respective zones of the framework.

The method may comprise attaching the components of the CMS associated with different lateral sides of the passenger cabin to two corresponding respective frameworks disposed adjacent one another and defining a corridor therebetween.

The method may comprise functionally integrating one or more of the components attached to one of the frameworks to one or more of the components attached to the other framework via a wire harness extending across the corridor defined between the two frameworks.

Embodiments may include combinations of the above features.

Further details of these and other aspects of the subject matter of this application will be apparent from the detailed description included below and the drawings.

### DESCRIPTION OF THE DRAWINGS

Reference is now made to the accompanying drawings, in which:

FIG. 1 is a schematic view of an exemplary test rig for performing functional tests on components of a cabin management system (CMS) of a mobile platform;

FIG. 2 is a schematic view of the test rig of FIG. 1 showing a top view of frameworks of the test rig;

FIG. 3 is a perspective view of an exemplary embodiment of the frameworks of FIG. 2;

FIG. 4 is a perspective view of a portion of a framework of FIG. 3 with exemplary components and wire harnesses attached thereto;

FIG. 5A is a perspective view of another portion of the framework of FIG. 3 with exemplary racks for receiving components therein;

FIG. 5B is a perspective view of the portion of framework including the racks of FIG. 5A where components are supported by the racks;

FIG. 6 is a perspective view of another portion of the framework where a component attached to one framework is functionally integrated with another component attached to the other framework; and

FIG. 7 is a flowchart of a method of performing functional tests on a CMS of an aircraft or other mobile platform.

### DETAILED DESCRIPTION

This disclosure relates generally to testing of systems for mobile platforms such as aircraft, trains, busses, ships and other vehicles. In particular, test rigs and methods disclosed herein may be suitable for performing functional tests on a cabin management system (CMS) of aircraft or other mobile platforms. In some embodiments, the test rig disclosed herein may facilitate some functional testing of a substantially complete, functionally-integrated CMS of an aircraft without the use of a flight test vehicle or of a dimensionally-representative (i.e., 1:1 scale) mock-up of the passenger cabin. For example, in some embodiments, the test rig may comprise one or more frameworks for supporting the functionally integrated components of the CMS where the layout of the components on the framework(s) is different from (e.g., non-dimensionally representative of) the layout of the components in the real passenger cabin of the aircraft. In other words, the layout of components on the framework(s) may be non-geometrically representative of the layout of the components in the real passenger cabin of the aircraft so that components of the CMS attached to the framework(s) are not in their exact respective positions that they occupy in the corresponding real passenger cabin.

The use of dimensionally-representative mock-ups provides limited flexibility in testing different configurations of aircraft cabins and/or different configurations of cabin management systems. The test rig disclosed herein may, in some embodiments, facilitate relatively rapid configuration changes in the CMS to accommodate different lengths and configurations of passenger cabins for example.

The use of dimensionally-representative mock-ups can require a large amount of space and be expensive. The test rig disclosed herein may, in some embodiments, have a smaller footprint than a dimensionally-representative mock-up of the passenger cabin. In some embodiments, the test rig disclosed herein may also promote a reduction in time required for installation and functional integration of the components of the CMS. In some embodiments, the test rig disclosed herein or part(s) thereof may be reused for functional testing of CMS of different aircraft types.

Aspects of various embodiments are described through reference to the drawings.

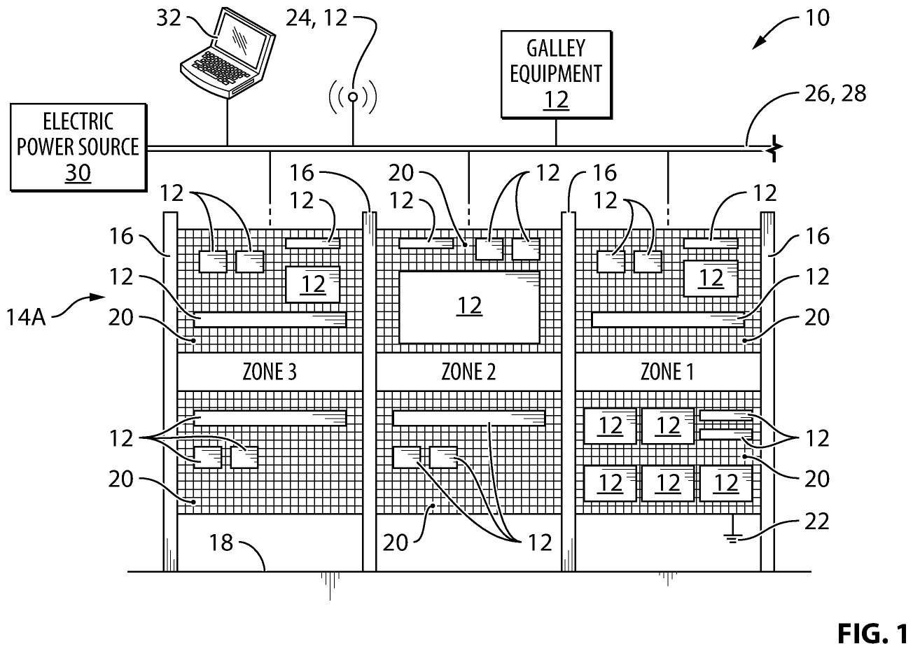

FIG. 1 is a schematic view of an exemplary test rig 10 for performing functional tests on components 12 of a CMS of a mobile platform such as an aircraft. Components 12 may comprise line-replaceable units. Components 12 may be associated with one or more sub-systems of the CMS where such sub-systems may be standalone or two or more of such sub-systems may be integrated together. For example, some of components 12 may be interconnected. As non-limiting examples, components 12 may be part of a lighting system, a climate control system, a sound system, an information system, an in-flight entertainment system, a (e.g., wireless) internet connectivity system, galley equipment, and/or window features (e.g., dimming window or window shades). In various embodiments, components 12 may include any of the following: (e.g., attendant call) buttons, switches, dials, touch-screens, user controls, display screens, computers, power conditioning equipment, (e.g., light) controllers, ordinance signs, media players, cameras, wireless access points, dimming windows, window shades, electrical power connectors for charging passenger-supplied personal electronic devices, lights, speakers, subwoofers, power outlets, data (e.g., universal serial bus (USB)) connectors, jacks, exemplary passenger-supplied devices for testing purposes, galley equipment (e.g., microwave oven and convection oven), modems and antennas. It is understood that components 12 are not limited to those listed above and that components 12 may comprise any devices associated with controlling the in-flight experience of passengers of the aircraft.

Test rig 10 may comprise framework 14A configured to support a plurality of components 12 to facilitate functional testing of components 12 while components 12 are functionally integrated in a manner representative of the installation of components 12 in the real passenger cabin of the aircraft. FIG. 1 shows a front view of framework 14A. Framework 14A may permit the attachment of components 12 thereto in a convenient and flexible manner so that the layout of components 12 is non-dimensionally-representative of the actual layout of components 12 in the real passenger cabin of the aircraft. For example, components 12 attached to framework 14A may be fully functionally integrated and therefore permit functional testing to be conducted on components 12 even though components 12 are not in their respective positions of installation in the passenger cabin.

In some embodiments, the plurality of components 12 may represent a substantially complete CMS so that functional testing on the entire CMS may be conducted in the absence of a flight test vehicle or a full-scale mock-up of the passenger cabin. Test rig 10 may permit the functional testing of sub-systems of interconnected components 12 and/or functional testing of individual components 12 of the CMS.

Test rig 10 may be installed in a ground-based facility (e.g., building). Test rig 10 may comprise one or more posts 16 extending substantially vertically from floor 18 of the ground-based facility. One or more support members 20 may be secured to posts 16 and may extend between posts 16. In some embodiments, support member(s) 20 may have an overall generally planar shape and may also be oriented generally vertically relative to floor 18 of the ground-based facility. For example, a normal of one or more support members 20 may be generally parallel to floor 18. In other words support member(s) 20 may each generally lie in a plane that is perpendicular to floor 18. In some embodiments, one or more support members 20 may not necessarily be perfectly perpendicular to floor 18 but may generally lie in a plane oriented at an oblique angle (i.e., neither perpendicular nor parallel) to floor 18. In various embodiments, one or more support members 20 may each generally lie in a plane that is non-parallel to floor 18.

Support members 20 may comprise features that facilitate the removable attachment of components 12 thereto in a simple and convenient manner. For example, such attachment features may be first attachment counterparts (e.g., holes and/or hooks) configured to interact with second attachment counterparts (e.g. VELCRO® straps and/or cable ties) to permit removable attachments of components to support members 20. For example, support members 20 may comprise a grillage or mesh including an array of spaced-apart bars or wires. In some embodiments, support members 20 may comprise an arrangement of criss-crossing bars or wires defining holes between such bars or wires. For example, each support member 20 may include an array of spaced-apart vertically-extending bars or wires combined with an array of spaced-apart horizontally-extending bars or wires. In various embodiments, such grillage may be configured to define an overall planar shape and/or a curved shape. As explained below, components 12 may be attached to support members 20 using any suitable temporary attachment means such as brackets, fasteners, VELCRO® straps and/or cable ties, also called “zip ties” or “tie wraps”, for example.

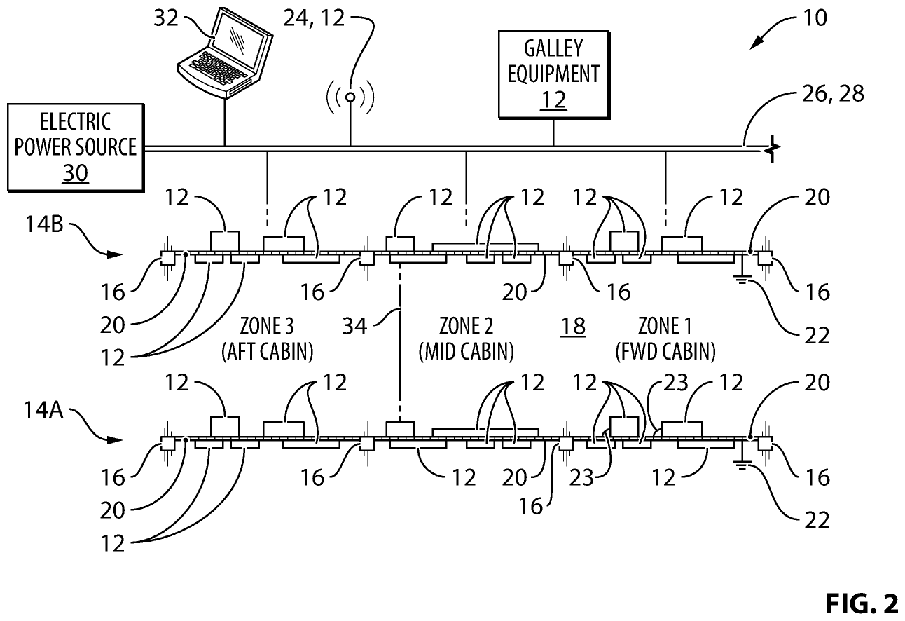

In some embodiments, framework 14A may comprise a plurality of spaced-apart posts 16 in a row with one or more support members 20 extending between each pair of posts 16 and being secured thereto. In some embodiments, support members 20 and/or posts 16 may be made from an electrically conductive (e.g., metallic) material such as a suitable steel or aluminum-based alloy for example. In some embodiments, one or more support members 20 may serve as a ground plane for one or more of components 12 attached thereto where the one or more support members 20 are electrically connected to ground 22. For example, one or more of components 12 may be electrically grounded to framework 14A via grounding connections 23 (shown in FIG. 2). Accordingly, the one or more support members 20 may provide an electrical return path for current from different components 12 attached thereto. In some embodiments, the one or more support members 20 may serve as a ground in a similar manner as a structure of the actual aircraft would in the actual installation of the CMS in the real passenger cabin. It is understood that separate electrical grounding may be provided instead of or in addition to support members 20. It is understood that support members 20 could instead be made from a substantially non-electrically-conductive material such as plastic or wood for example.

Components 12 may be temporarily and removably attached to support members 20 and fully functionally integrated so that functional testing may be performed. Therefore, the functional integration of components 12 of the CMS may be functionally representative of the actual installation in the real passenger cabin of the aircraft. In various embodiments, one or more components 12 may be interconnected together. Wiring has been omitted from FIG. 1 for clarity but it is understood that components 12 would be functionally connected and integrated using actual installation wire harnesses that are dimensionally representative (i.e., true-to-scale) even though the geometric layout of components 12 on support members 20 may be different from the actual layout of components 12 in the real passenger cabin of the aircraft.

In various embodiments, some (e.g., larger) galley equipment may be supported by framework 14A or may be disposed at some other location that is sufficiently close to framework 14A so that it may also be functionally integrated with other components 12 as required for the purpose of functional testing. Similarly, one or more (e.g., satellite communications (SATCOM) and/or Iridium) antennas 24 that may be part of the CMS may be disposed at some other more convenient or appropriate location that is sufficiently close to framework 14 so that it may also be functionally integrated with other components 12 as required for the purpose of functional testing. In some embodiments, antennas 24 may be disposed on a roof of a building housing framework 14A for example.

The functional integration of components 12 may include connections to one or more data busses 26 (e.g., Aeronautical Radio INC. (ARINC)) and/or one or more power busses 28 shown together for clarity in FIG. 1. Components 12 may be connected to a suitable electric power source 30 via power bus 28. Power source 30 may be configured to simulate one or more electric power busses of the aircraft into which the CMS is to be installed. For example, power source 30 and power bus 28 may form an experimental power distribution system. For example, power source 30 may comprise one or more industrial power supplies that provide power to aircraft type breakers. Power source 30 may be configured to allow variation of power supply frequency and voltage to validate the functionality of components 12 within a desired operational envelope.

Similarly, data bus 26 may simulate an actual data bus of the aircraft into which the CMS is to be installed. It is understood that data communication with components 12 and/or between components 12 may be established via wired or wireless connections. Data bus(ses) 26 may be configured to simulate one or more types of data busses such as ARINC, CANBus, Ethernet-based topologies or other suitable protocols for functionally testing the operation of CMS messaging for simulated geo-locational data for example.

Test rig 10 may comprise one or more computers 32 from which functional testing of components 12 of CMS may be conducted and controlled. For example, computer 32 may be in data communication with one or more of components 12 and with electric power source 30 via data bus 26 or otherwise. In some embodiments, computer 32 may be configured to issue commands and/or receive feedback from one or more components 12 to test their functionality. Computer 32 may simulate other avionics equipment that may interface with the CMS in the real installation. Computer 32 may be configured to cause components 12 to carry out tasks so that the functionality of components 12 may be assessed.

Even though the layout of components 12 on framework 14A may not be dimensionally-representative of the installation of components 12 in the real passenger cabin of the aircraft, the relative positioning of components 12 may be partly representative of the real installation in some embodiments. For example, framework 14A may have a plurality of zones (e.g., ZONES 1, 2 and 3) where each zone of framework 14A supports one or a group of components 12 that are to be installed in corresponding zones of the real passenger cabin. For example, ZONE 1 of framework 14A may support components 12 to be installed in a forward zone of the passenger cabin; ZONE 2 of framework 14A may support components 12 to be installed in a middle zone of the passenger cabin; and ZONE 3 of framework 14A may support components 12 to be installed in an aft zone of the passenger cabin. It is understood that any number of zones may be defined on framework 14A based on the configuration of the passenger cabin. The use of such zones on framework 14A may facilitate the installation, functional testing and troubleshooting of components 12.

FIG. 2 is another schematic view of test rig 10 for performing functional tests on components 12 of the CMS. FIG. 2 shows a top view of framework 14A. Test rig 10 may also comprise another framework 14B which may be disposed sufficiently near framework 14A so that part of the same CMS may be supported by both framework 14A and framework 14B. It is understood that one or more additional frameworks may also be part of test rig 10. The use of two or more frameworks 14A, 14B disposed adjacent one another may also promote the efficient use of space of test rig 10. For example, the positioning of framework 14A and framework 14B may define a three-corridor configuration where one access corridor is defined between framework 14A and framework 14B and respective access corridors are define to the exterior of framework 14A and framework 14B. In some embodiments, components 12 may be attached to both (i.e., front and back) sides of support members 20 so as to provide access to components 12 from each of the three corridors and promote efficient use of space.

In the dual framework embodiment illustrated, framework 14A may be used to support components 12 associated with (e.g., to be installed on) a first lateral side (e.g., starboard) side of the passenger cabin and framework 14B may be used to support components 12 associated with (e.g., to be installed on) a second lateral (e.g., port) side of the passenger cabin. Components 12 associated with the first lateral side may be positioned on both (i.e., front and back) sides of framework 14A and components 12 associated with the second lateral side may be positioned on both (i.e., front and back) sides of framework 14B. In some embodiments, one or more components 12 supported by framework 14A may be connected to one or more components 12 supported by framework 14B as represented in FIG. 2 by wire harness 34 extending across the middle corridor defined between framework 14A and framework 14B. It is understood that test rig 10 may be configured to provide additional corridors depending on the configuration of the passenger cabin and/or the configuration and size of the space available for housing test rig 10.

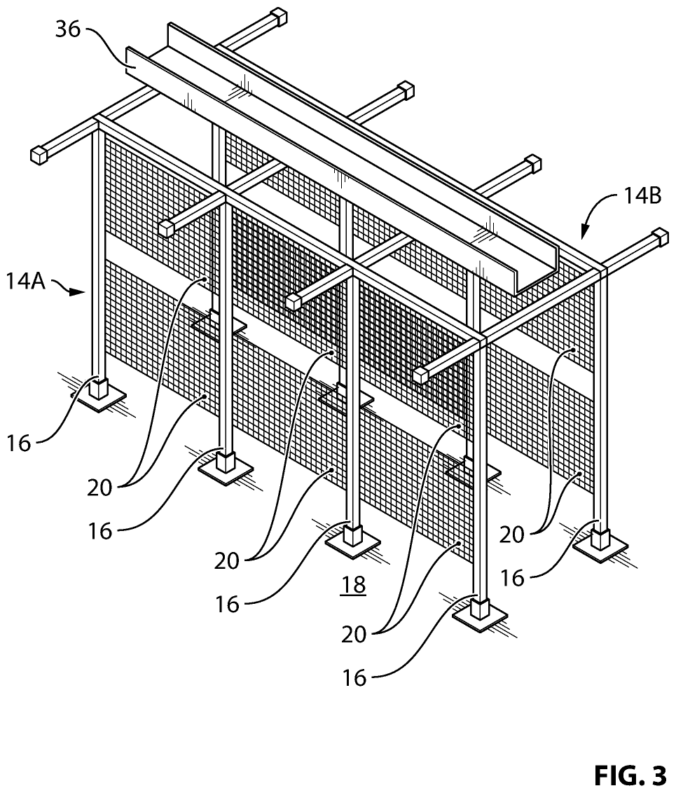

FIG. 3 is a perspective view of an exemplary embodiment of framework 14A comprising posts 16 and support members 20. In this embodiment, support members 20 and posts 16 are made from steel. For example, support members 20 may comprise steel grillage or mesh having a generally planar configuration and posts 16 may comprise steel channels. In some embodiments, test rig 10 may also comprise an overhead trough 36 (e.g., C-shaped channel) suitable for supporting one or more wire harnesses associated with data bus 26 and/or with power bus 28 for example.

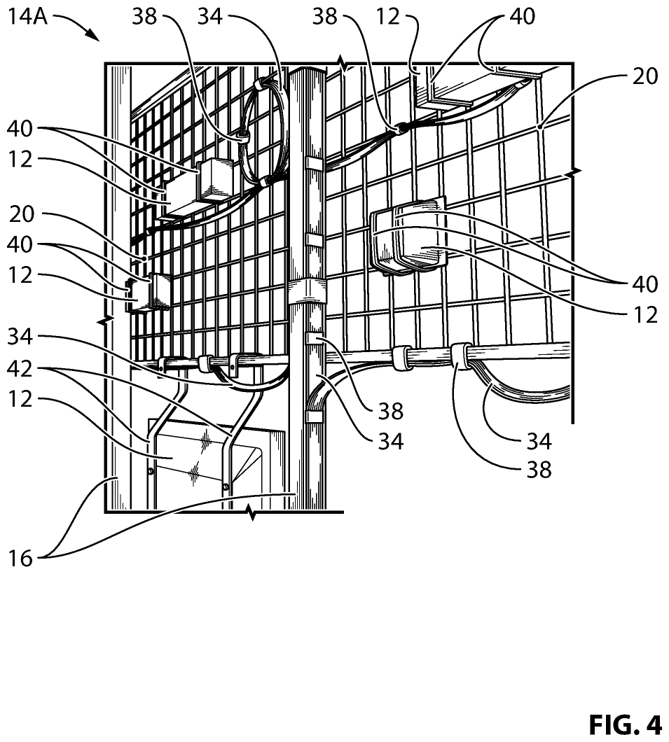

FIG. 4 is a perspective view of portion of framework 14A with components 12 and wire harnesses 34 attached thereto. Components 12 may be temporarily attached to support members 20 and/or posts 16 using any suitable means. In some embodiments, some components 12 and/or wire harnesses 34 may be attached using one or more VELCRO® straps 38 for example. In some embodiments, some components 12 and/or some wire harnesses 34 may be attached using one or more cable ties 40 for example. In some embodiments, some components 12 (e.g., display screen) and/or wire harnesses 34 may be attached using one or more brackets 42 for example.

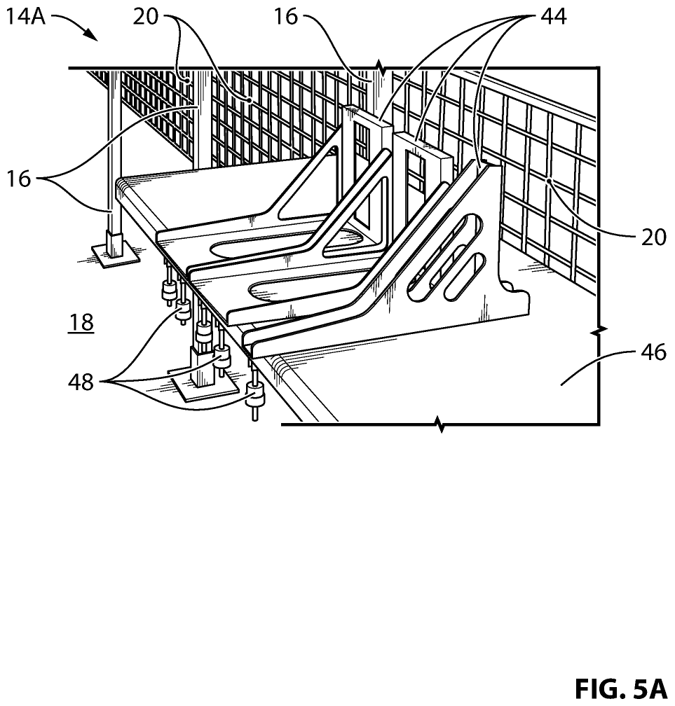

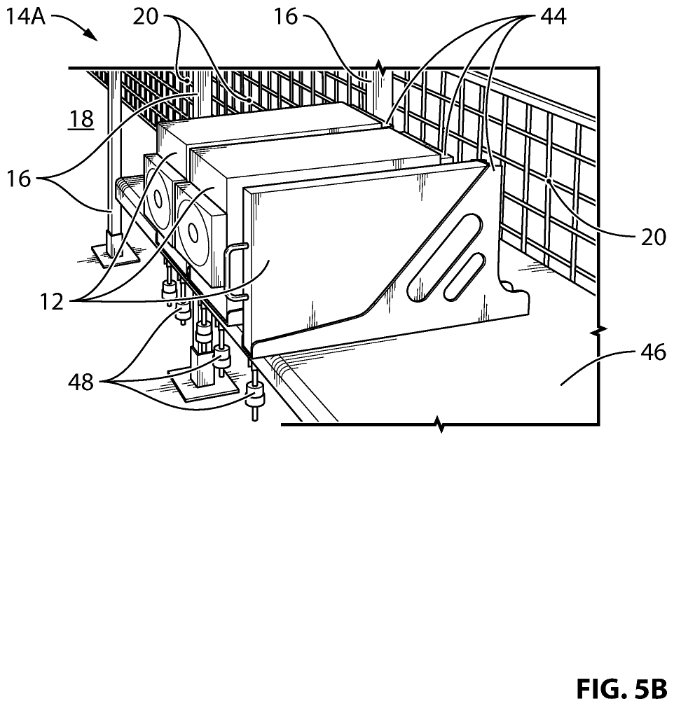

FIG. 5A is a perspective view of another portion of framework 14A showing exemplary racks 44 for receiving components 12 therein. Racks 44 may be directly or indirectly attached to support members 20 and/or to posts 16 in any suitable manner. As shown in FIG. 5 for example, racks 44 may be attached to support members 20 and/or posts 16 via shelf 46. In some embodiments, racks 44 may be attached to shelf 46 using one or more clamps 48.

FIG. 5B is a perspective view of the portion of framework 14A including racks 44 shown in FIG. 5A where components 12 are supported by racks 44, which are in turn supported by framework 14A via shelf 46.

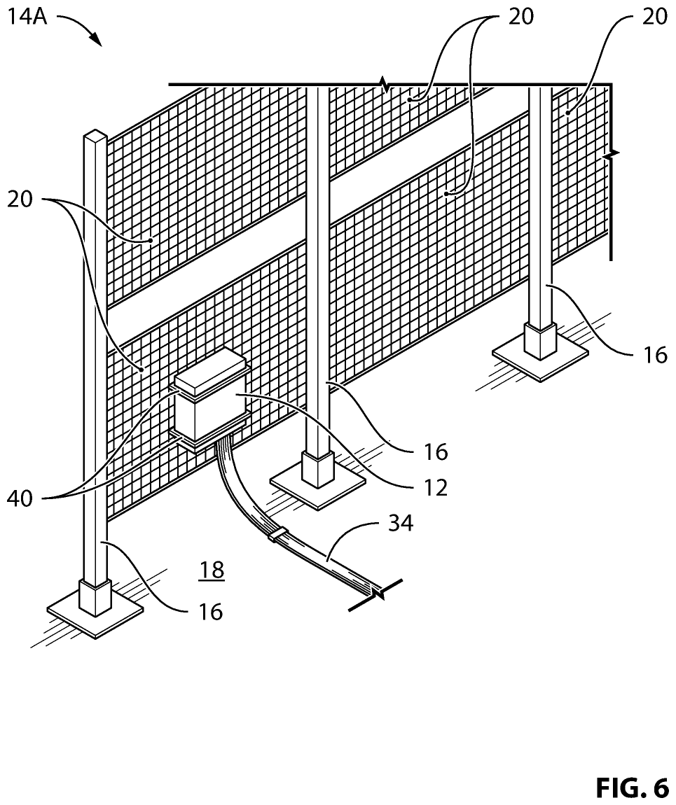

FIG. 6 is a perspective view of a portion of framework 14A including an exemplary component 12 which is connected to another component 12 disposed on framework 14B (not shown in FIG. 6) via wire harness 34. As also shown in FIG. 2, wire harness 34 may extend between framework 14A and framework 14B and may consequently extend across the middle corridor defined between framework 14A and framework 14B. The spacing between framework 14A and framework 14B and the height of component 12 above floor 18 may be selected so that the length of wire harness 34 may be the same length as when installed in the actual passenger cabin and that wire harness 34 may be safely routed on floor 18 and protected by cover 50.

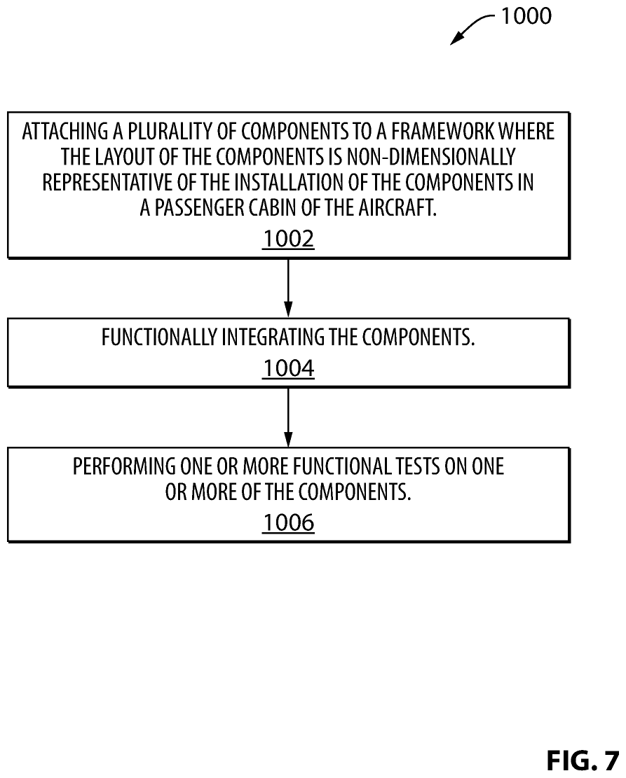

FIG. 7 is a flowchart of a method 1000 of performing functional tests on a CMS of an aircraft or other mobile platform. Method 1000 may be conducted using test rig 10 as disclosed herein or using other suitable means. Aspects of the description provided above in relation to test rig 10 may also apply to method 1000.

In some embodiments, method 1000 may comprise: attaching a plurality of components 12 of the CMS to framework 14A where the layout of the plurality of components 12 is non-dimensionally representative of the installation of components 12 in the passenger cabin of the aircraft (see block 1002); functionally integrating components 12 in a manner representative of the installation of components 12 in the passenger cabin of the aircraft (see block 1004); and then performing one or more functional tests on one or more of the plurality of components 12.

In some embodiments, method 1000 may comprise attaching one or more of components 12 to opposite generally planar sides of framework 14A.

In some embodiments, method 1000 may comprise electrically grounding one or more of components 12 to framework 14A.

In some embodiments, method 1000 may comprise functionally integrating components 12 via one or more wire harnesses 34 dimensionally-representative of the installation of components 12 in the passenger cabin.

In some embodiments, method 1000 may comprise attaching components 12 of the CMS associated with different passenger cabin zones to corresponding respective zones of framework 14A.

In some embodiments, method 1000 may comprise attaching components 12 of the CMS associated with different lateral sides of the passenger cabin to two corresponding respective frameworks 14A, 14B disposed adjacent one another and defining a corridor therebetween.

In some embodiments, method 1000 may comprise functionally integrating one or more of components 12 attached to one of frameworks 14A or 14B to one or more of components 12 attached to the other framework 14A or 14B via a wire harness extending across the corridor defined between frameworks 14A, 14B.

The above description is meant to be exemplary only, and one skilled in the relevant arts will recognize that changes may be made to the embodiments described without departing from the scope of the invention disclosed. The present disclosure may be embodied in other specific forms without departing from the subject matter of the claims. The present disclosure is intended to cover and embrace all suitable changes in technology. Modifications which fall within the scope of the present invention will be apparent to those skilled in the art, in light of a review of this disclosure, and such modifications are intended to fall within the appended claims. Also, the scope of the claims should not be limited by the preferred embodiments set forth in the examples, but should be given the broadest interpretation consistent with the description as a whole.

1. A test rig for performing functional tests on a cabin management system (CMS) of a passenger cabin of an aircraft or other mobile platform, the test rig comprising:
a plurality of components of the CMS functionally integrated in a manner representative of the installation of the components in the passenger cabin; and
a framework supporting the functionally integrated components, the layout of the components on the framework being non-dimensionally representative of the installation of the components in the passenger cabin.

2. The test rig as defined in claim 1, wherein:
the framework comprises a generally planar support member to which one or more of the components are attached; and
the framework is located at a ground-based facility and the planar support member is generally vertical relative to a floor of the ground-based facility.

3. The test rig as defined in claim 1, wherein:
the framework comprises a generally planar support member to which one or more of the components are attached; and
the framework is located at a ground-based facility and the planar support member is non-parallel to a floor of the ground-based facility.

4. The test rig as defined in claim 2, wherein the support member comprises a plurality of attachment features configured to permit removable attachment of the components to the support member.

5. The test rig as defined in claim 4, wherein the attachment features comprise holes.

6. The test rig as defined in claim 2, wherein the support member extends between two posts.

7. The test rig as defined in claim 2, wherein the support member comprises a grillage.

8. The test rig as defined in claim 2, wherein components are attached to opposite generally planar sides of the support member.

9. The test rig as defined in claim 1, wherein the framework comprises a grillage to which one or more of the components are attached.

10. The test rig as defined in claim 1, wherein one or more of the components are attached to the framework with a VELCRO strap.

11. The test rig as defined in claim 1, wherein one or more of the components are attached to the framework with a cable tie.

12. The test rig as defined in claim 1, wherein one or more of the components are attached to the framework via a rack.

13. The test rig as defined in claim 1, wherein one or more of the components are electrically grounded to the framework.

14. The test rig as defined in claim 1, wherein the components are functionally integrated via dimensionally-representative wire harnesses.

15. The test rig as defined in claim 1, comprising a power source electrically connected to one or more of the components, the power source being configured to simulate one or more electric busses of the mobile platform.

16. The test rig as defined in claim 1, wherein the framework comprises a plurality of test rig zones respectively corresponding to passenger cabin zones, the test rig zones respectively supporting one or more of the components associated with the respective passenger cabin zones.

17. The test rig as defined in claim 1, comprising two frameworks disposed adjacent one another to define a corridor between the two frameworks.

18. The test rig as defined in claim 17, wherein each framework respectively supports one or more of the components associated a respective lateral side of the passenger cabin.

19. The test rig as defined in claim 18, wherein one or more of the components supported by one of the frameworks are functionally connected to one or more of the components supported by the other framework via a wire harness extending across the corridor defined between the two frameworks.

20. The test rig as defined in claim 1, wherein the plurality of components include one or more line-replaceable units associated with two or more of the following systems of the passenger cabin: a lighting system, a climate control system, a sound system, an information system, an in-flight entertainment system and an internet connectivity system.

21.-27. (canceled)
